(19) United States
(12) Patent Application Publication
(10) Pub. No.: US 2026/0296373 A1
(43) Pub. Date: Oct. 1, 2026

(54) Security Cover Systems

(71) Applicant: Travis Allen Jewell, Tyler, TX (US)

(72) Inventor: Travis Allen Jewell, Tyler, TX (US)

(21) Appl. No.: 19/577,930

(22) Filed: Mar. 25, 2026

Related U.S. Application Data
(60) Provisional application No. 63/780,432, filed on Mar. 30, 2025.

(51) Int. Cl. B60R 25/34; B32B 5/02; B32B 5/26; B60J 11/04; B60R 25/01; B60R 25/10; B60R 25/102; B63B 17/00; B63B 17/02; B63B 45/08; B63B 79/10; B65D 71/00; G01R 31/54

(52) U.S. Cl. CPC B60R 25/34; B32B 5/028; B32B 5/26; B60J 11/04; B60R 25/01; B60R 25/1004; B60R 25/102; B63B 17/02; B63B 45/08; B63B 79/10; B65D 71/0096; G01R 31/54; B32B 2307/202; B60R 2025/1016; B63B 2017/0009; B65D 2571/00012

(57) ABSTRACT

A security cover system includes a fabric portion surrounded by a perimeter section. The fabric portion is dimensioned to selectively extend so as to envelop or partially enclose an object. A cut sensor is integrated into a section of the fabric portion and includes a mesh incorporated within the fabric material. The cut sensor is configurable in an armed state in which a signal is communicated through the mesh, such that disruption of the mesh interrupts the signal. A hub is in operable communication with the cut sensor and is configured to detect interruption of the signal and, in response, generate and communicate an alarm indicating a breach of the fabric portion.

### CROSS-REFERENCE TO RELATED APPLICATION

This application claims priority to and the benefit of U.S. Provisional Application no. 63/780,432 filed Mar. 30, 2025, which is incorporated herein by reference in its entirety.

### FIELD

Embodiments of the present disclosure related to security cover systems. In particular, embodiments relate to multi-featured cut and tamper detection security covers.

### BACKGROUND

Conventional boat and vehicle covers are primarily passive deterrents. These boat and vehicle covers may include cinch straps, snaps, or locks. However, these conventional covers do not actively detect intrusion. Thieves can simply cut through the cover or quietly remove the straps and gain access to the object or valuables stored therein. Some boats and vehicles are fitted with security systems such as GPS tracking or motion alarms. However these security systems do not detect physical breaches to the covering. Accordingly, there is a need in the field of protective coverings for a system that actively monitors for physical intrusion and cover removal and alarms when such physical intrusion is identified.

The subject matter claimed herein is not limited to embodiments that solve any disadvantages or that operate only in environments such as those described. Rather, this background is only provided to illustrate one example technology area where some embodiments described herein may be practiced.

### SUMMARY

According to an aspect of the invention, an embodiment includes a security cover system. The security cover system may include a fabric portion surrounded by a perimeter section. The fabric portion may be sized to be selectively extended to envelop or partially enclose an object. The security cover system may include a cut sensor integrated into a first section of the fabric portion, the cut sensor including a mesh integrated into material of the fabric portion, wherein the cut sensor is configurable in an armed state in which a signal is communicated through the mesh and disruption to the mesh interrupts communication of the signal. The security cover system may include a hub in operable communication with the cut sensor such that interruption to the signal is identified by the hub and responsive to identification of the interruption, the hub generates and communicate an alarm. The security cover system may include an object attachment feature including a connector that is configured to selectively secure the flexible portion relative to the object. The security cover system may include a secondary sensor associated with the object attachment feature. The secondary sensor is configurable in the armed state in which an additional signal is communicated through the connector such that disengagement of the connector interrupts the additional signal. The hub may be in operable communication with the secondary sensor such that the disengagement of the connector is identified by the hub and responsive to the identification of the disengagement, the hub generates and communicates the alarm. The cut sensor and the secondary sensor may be further configurable in a disarmed state during which the signal and the additional signal are not communicated.

According to another aspect of the invention, an embodiment includes a boat cover including a security system. The boat cover may include a fabric portion surrounded by a perimeter section. The fabric portion is sized to be selectively extended across a gunwale of a boat to enclose or substantially enclose a portion of a cockpit of the boat. The perimeter section is located along an edge of the fabric portion. The fabric portion is comprised of an inner layer of material that at least partially faces the boat when the fabric portion is extended across the gunwale and an outer layer of material that is subject to an environmental condition when the fabric portion is extended across the gunwale. The boat cover may include a cut sensor integrated into a first section of the fabric portion. The cut sensor includes a mesh integrated between the outer layer and the inner layer. The cut sensor is configurable in an armed state in which a first signal is communicated through the mesh and disruption to the mesh interrupts communication of the signal. The boat cover may include an attachment feature that is configured to selectively secure the flexible portion relative to the boat. The boat cover may include a secondary sensor associated with the attachment feature. The secondary sensor is configurable in the armed state in which an additional signal is communicated through an element of the attachment feature such that disengagement of the attachment feature interrupts the additional signal. The boat cover may include a hub in operable communication with the cut sensor and the secondary sensor. The hub may include a monitor that identifies an interruption to the first signal and interruption of the additional signal, and an alarm that is triggered responsive to identification of the interruption of the first signal or the interruption of the additional signal.

The object and advantages of the embodiments will be realized and achieved at least by the elements, features, and combinations particularly pointed out in the claims. It is to be understood that both the foregoing general description and the following detailed description are exemplary and explanatory and are not restrictive of the invention, as claimed.

### BRIEF DESCRIPTION OF THE DRAWINGS

Example embodiments will be described and explained with additional specificity and detail through the use of the accompanying drawings in which:

FIGS. 1A and 1B depict a boat cover that is an example of a security cover system;

FIG. 2 is a diagram of an example sensor assembly that may be integrated into the boat cover of FIGS. 1A and 1B or another suitable security cover system;

FIGS. 3A and 3B depict an example mesh assemblies that may be implemented in the sensor assembly of FIG. 2, the boat cover of FIGS. 1A and 1B, or another suitable security cover system;

FIGS. 4A-4D depict example embodiments of secondary sensors that may be integrated into attachment features, which may be included in boat cover of FIGS. 1A and 1B, or another suitable security cover system;

FIG. 5A is a first example of an additional secondary sensor which may be included in boat cover of FIGS. 1A and 1B, or another suitable security cover system;

FIG. 5B is a second example of the additional secondary sensor which may be included in boat cover of FIGS. 1A and 1B, or another suitable security cover system;

FIGS. 6A and 6B depict a block diagram of an example embodiment of a hub that may be included into the boat cover of FIGS. 1A and 1B or another suitable security cover system;

FIG. 7 depicts another example embodiment of a flexible security cover implemented on a kiosk; and

FIG. 8 depicts another example embodiment of a flexible security cover implemented on a vehicle,

all in accordance with at least one embodiment of the present disclosure.

### DESCRIPTION OF SOME EXAMPLE EMBODIMENTS

The embodiments described in this disclosure are related to security cover systems. The security cover systems are configured to cover an object or a portion thereof. The systems include security features that monitor for physical breaches such as cuts or unauthorized removal of the cover and include a smart notification system that notifies a user when the physical breach(es) occur. In particular, embodiments relate to multi-featured cut and tamper detection security covers that may be implemented relative to a boat, kiosk, vehicle, etc. Each of these security features are integrated into the cover of a component of the cover. The security features are connected to a hub, which enables the security features to be activated or armed. After the security features are armed, the security features detect cuts, unauthorized removal, etc. and communicate a notification to a user.

The security features are integrated into flexible, fabric-based protective covers. Thus, the object being covered benefits from protection provided by protective covers such as environmental protection (e.g., sun, rain, wind, dust, etc.). In addition, the security features add an additional layer of protection when an unauthorized individual or a bad actor attempts to remove or destroy the cover.

Accordingly, the security cover system enables secure storage of objects. For instance, the security cover system covers portions or extends across defined volumes of objects. The security cover system may include a cut sensor. When a bad actor cuts a fabric portion of the security cover system, the cut sensor is triggered, which results in the hub communicating an alert to a user or another interested party Additionally, embodiments of the security cover system include a secondary sensor. The secondary sensor is configured to sense an unauthorized removal or damage to an object attachment feature of the security cover system. The secondary sensor alerts the user to the attempted unauthorized removal of the system. Thus, the security cover system prevents unauthorized access to the object or covered portion thereof by a bad actor cutting a fabric portion of the system or by damaging or removing the object attachment feature.

The security cover system is particularly useful in protecting items stored in the object, which is then covered by the security cover. For instance, many fisherman store fishing poles and fishing equipment on their boat. Conventional boat covers leave these items vulnerable to theft. For instance, the thief may simply cut the conventional cover and pull the fishing equipment from the boat. In contrast, with the security cover system, the fishing equipment is safely stored in the boat. Specifically, if the thief cuts the security cover system, the fisherman will be alerted. Similarly, if the thief attempt to remove the security cover system after it is armed, the fisherman will be altered.

These and other embodiments are described with reference to the appended Figures in which like item number indicates like function and structure unless described otherwise. The configurations of the present systems and methods, as generally described and illustrated in the Figures herein, may be arranged and designed in different configurations. Thus, the following detailed description of the Figures, is not intended to limit the scope of the systems and methods, as claimed, but is merely representative of example configurations of the systems and methods.

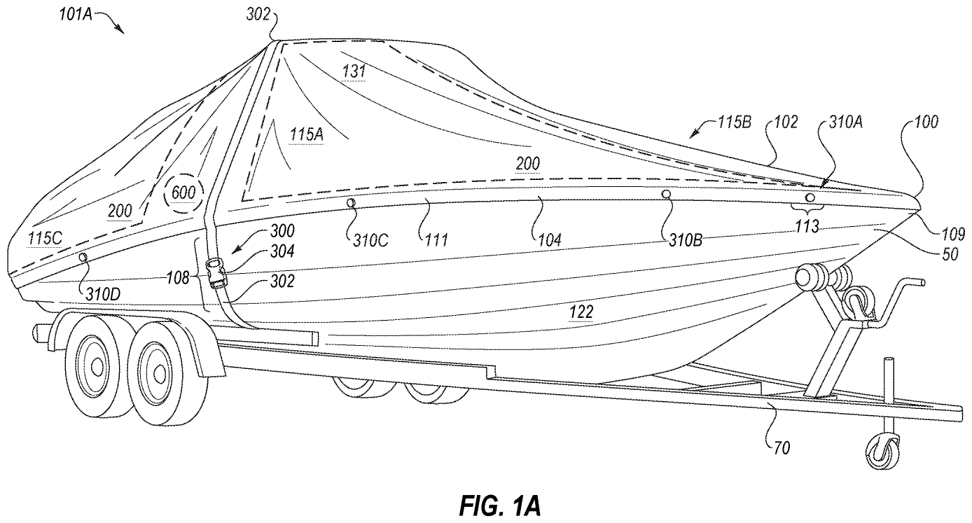

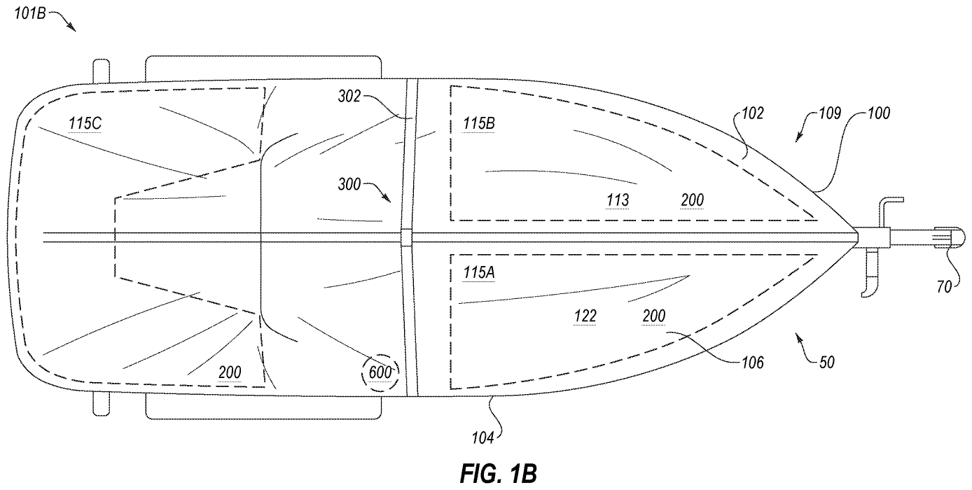

FIGS. 1A and 1B depict a boat cover 100 according to some embodiments of the present disclosure. The boat cover 100 is an example of a security cover system that is physically configured to be implemented with a boat 50. The boat cover 100 integrates security features that trigger an alarm responsive to a rupture or tear in a fabric portion 102 and/or responsive to an unauthorized removal of the fabric portion 102 from the boat 50. As described elsewhere in the present disclosure, the security feature that triggers the alarm responsive to the rupture or tear is referred to a cut sensor 106. The security feature that triggers the alarm responsive to unauthorized removal of the fabric portion 102 is referred to as a secondary sensor 108.

The cut sensor 106 is integrated into the fabric portion 102 of the boat cover 100. For instance, the cut sensor 106 may include a mesh 200 that, when armed communicates a signal such as an electrical signal. A cut to the fabric portion 102 disrupts the signal. A hub 600 is communicatively coupled to the mesh 200 and monitors for the mesh 200 to detect the disruption. Responsive to the disruption, the alarm is triggered.

The secondary sensor 108 is integrated into an attachment feature 300 of the boat cover 100. The attachment feature 300 secures or partially secures the fabric portion 102 relative to the boat 50. For instance, in FIG. 1A, the attachment feature 300 is a strap 302 that extends from a perimeter section 104 of the fabric portion 102. The strap 302 extends along an exterior hull 122 of the boat 50 to secure the fabric portion 102 relative to the boat 50. The secondary sensor 108, is placed in an armed state when the attachment feature 300 is fastened or otherwise actuated to secure the boat cover 100 to the boat 50. When the secondary sensor 108 is in the armed state, an additional signal is communicated through the secondary sensor 108. Similarly to the cut sensor 106, the hub 600 monitors for disruptions to the additional signal and triggers an alarm responsive to such disruptions. The disruptions may be caused by cutting or damaging the attachment feature 300 or deactivating or removing the attachment feature 300.

Accordingly, as described more fully below, the boat cover 100 provides security features such as the cut sensor 106 and the secondary sensor 108 that trigger an alarm when the fabric portion 102 is cut and/or when the attachment feature 300 is damaged or removed. Thus, the boat cover 100 implemented on the boat 50 prevents or reduces access to an interior portion or cabin of the boat 50, enables equipment to be stored in the interior portion or the cabin, and also provides protection from environmental conditions that a conventional cover provides.

Referring to FIGS. 1A and 1B, an external, perspective view 101A of the boat cover 100 is depicted in FIG. 1A and a top view 101B of the boat cover 100 is depicted in FIG. 1B. The boat cover 100 is positioned on the boat 50, which is positioned on a trailer 70 in FIGS. 1A and 1B. The depiction in FIGS. 1A and 1B is a common storage arrangement in which the boat 50 is covered. Alternatively, the boat 50 may be stored in the water (e.g., at a pier or slip) or may be located in a dry dock or dry stock. In these alternatives, the boat cover 100 may be secured relative to the boat 50 as well.

The boat cover 100 includes the fabric portion 102, which is surrounded by the perimeter section 104. The fabric portion 102 is sized to be selectively extended across a gunwale 109 of the boat 50 to enclose or substantially enclose at least a portion of a cockpit of the boat 50. In FIGS. 1A and 1B, the cockpit is not visible because the boat cover 100 is concealing it. However, the cockpit may house controls, seating, engine, equipment storage, etc. of the boat 50. The perimeter section 104 is generally along an edge 111 of the fabric portion 102.

The fabric portion 102 includes an exterior or outer layer 131. The outer layer 131 may be comprised of a layer of material. The outer layer 131 is subject to environmental condition when the fabric portion 102 is extended across the gunwale 109. Opposite the outer layer 131 may be an inner layer that faces the cockpit of the boat 50 when the boat cover 100 is secured relative to the boat 50.

The fabric portion 102 includes one or more sections 115A-115C (generally, section 115 or sections 115). The cut sensor 106 or portions of the cut sensor 106 may be integrated into one or more or each of the sections 115. For example, the mesh 200 or portions of the mesh 200 may be integrated into the sections 115. Accordingly, a cut or a tear the mesh 200 in the sections 115 triggers the alarm.

In the embodiment of FIGS. 1A and 1B, there are three sections 115. A first section 115A is located on a starboard forward portion of the fabric portion 102, a second section 115B is located on a port forward portion of the fabric portion 102, and a third section 115C is located along the aft portion of and extends forward up a portion of the sides. In some embodiments, there may be two sections 115, one on the port side and another on the starboard side. In some embodiments, there may be a single section 115 that extends a particular distance (e.g., six inches, ten inches, fifteen inches, etc.) from the edge 111. In some embodiments, the cut sensor 106 and the mesh 200 may be integrated throughout the entire fabric portion 102. In these and other embodiments, the mesh 200 or portions thereof may be integrated into the sections such that a cut or a tear to the mesh 200 in the section(s) 115 triggers the alarm.

The boat cover 100 includes the attachment feature 300 that is configured to selectively secure the fabric portion 102 relative to the boat 50. Multiple types of attachment features 300 may be implemented in the boat cover 100. For instance, in FIGS. 1A and 1B, the attachment feature 300 includes a strap 302 and a connector 304 (FIG. 1A only). The strap 302 extends from the perimeter section 104 underneath the boat 50. The connector 304 enables a user to tighten the strap 302, which tightens the fabric portion 102 relative to the boat 50. Other examples of the attachment feature 300 are described elsewhere in the present disclosure.

In the boat cover 100, the secondary sensor 108 is integrated into the attachment feature 300. For example, when the attachment feature 300 is engaged, (e.g., the connector 304 has been implemented to tighten the strap 302 against the exterior hull 122), the secondary sensor 108 may be armed. In the armed state, an additional signal is communicated from the hub 600 through a portion of the fabric portion 102, through the strap 302, and through the connector 304. In this embodiment, the secondary sensor 108 is a circuit that is completed or closed when the attachment feature 300 is engaged. Disengagement of the attachment feature 300 such as by cutting the strap 302 or disengaging the connector 304 interrupts or opens the circuit. Thus, the additional signal is disrupted. The hub 600 monitors for disruptions to the additional signal and the disruption triggers the alarm. Accordingly, the secondary sensor 108 may alarm responsive to an unauthorized disengagement of the connector 304 as well as damage to the strap 302 or the connector 304.

Additionally, referring to FIG. 1A, the boat cover 100 includes snap connectors 310A-310D (generally snap connectors 310 or snap connector 310). The snap connectors 310 are positioned along the perimeter section 104 of the boat cover 100. The snap connectors 310 are sized and configured to be engaged with corresponding snap features on the boat 50. For instance, the snap connectors 310 may be female or receiving snap connectors. The boat 50 may have male snap connectors that are sized to be securely received into the female snap connectors 310. When engaged relative to the corresponding snap connectors of the boat 50, the snap connectors 310 may secure the fabric portion 102 relative to the boat 50.

Similar to the secondary sensor 108, an additional secondary sensor 113 may be integrated into the snap connectors 310. For instance, a communication element (not visible in FIG. 1A) may be integrated into the perimeter section 104. The communication element communicatively couples the snap connectors 310 to the hub 600. When the snap connectors 310 are engaged to secure the fabric portion 102 relative to the boat 50, a circuit is complete. The additional secondary sensor 113 may be armed. When armed, an additional secondary signal is communicated from the hub 600 through the communication element and through the snap connectors 310. Disengaging the snap connectors 310 from corresponding connectors on the boat 50 interrupts the circuit and prevents the additional secondary signal. The hub 600 monitors for interruption to the additional secondary signal and may trigger the alarm responsive to such interruption.

In some embodiments, multiple secondary sensors 108 or multiple additional secondary sensors 113 may be integrated into the boat cover 100. For instance, the boat cover 100 might include multiple straps 302, each of which may include secondary sensors 108. Similarly, the boat cover 100 might include separate portions each include a set of snap connectors. In these embodiments, each of the sets of snap connectors may integrate an additional secondary sensor 113. Moreover, in some embodiments, the boat cover 100 may not include the secondary sensor 108 or the additional secondary sensor 113. For instance, the boat cover 100 may only include the cut sensor 106.

As introduced above, the cut sensor 106, the secondary sensor 108, and the additional secondary sensor 113 may be configured in an armed state. In some embodiments, the boat cover 100 may be installed or secured relative to the boat 50. For instance, the fabric portion 102 is positioned over the gunwale 109, the strap 302 and connector 304 are tightened, and the snap connectors 310 are engaged. After the boat cover 100 is secured, the cut sensor 106, the secondary sensor 108, the additional secondary sensor 113, or some combination thereof may be armed. Once armed, the signals are communicated through the armed sensors 106/108/113. The hub 600 monitors for interruptions to the signals. For instance, the interruptions may be caused by cutting the mesh 200, cutting the strap 302, disengaging one or more of the snap connectors 310, disengaging the connector 304, or some combination thereof. Responsive to the interruption, the alarm is triggered.

Additionally, the cut sensor 106, the secondary sensor 108, and the additional secondary sensor 113 or some combination thereof may be configured in a disarmed state. The disarmed state stops the signals from being communicated from the hub 600. For instance, when all of the sensors 106/108/113 are disarmed, the boat cover 100 may be removed and stored by a user. Alternatively, a portion of the boat cover 100 may be torn due to environmental conditions or otherwise damaged. Thus, the user might opt to disarm the cut sensor 106 and arm the secondary sensor 108 and the additional secondary sensor 113. Additionally still, the boat 50 might be stored in the water. Thus, positioning the strap 302 under the exterior hull 122 may not be possible. Accordingly, the cut sensor 106 and the additional secondary sensor 113 might be armed.

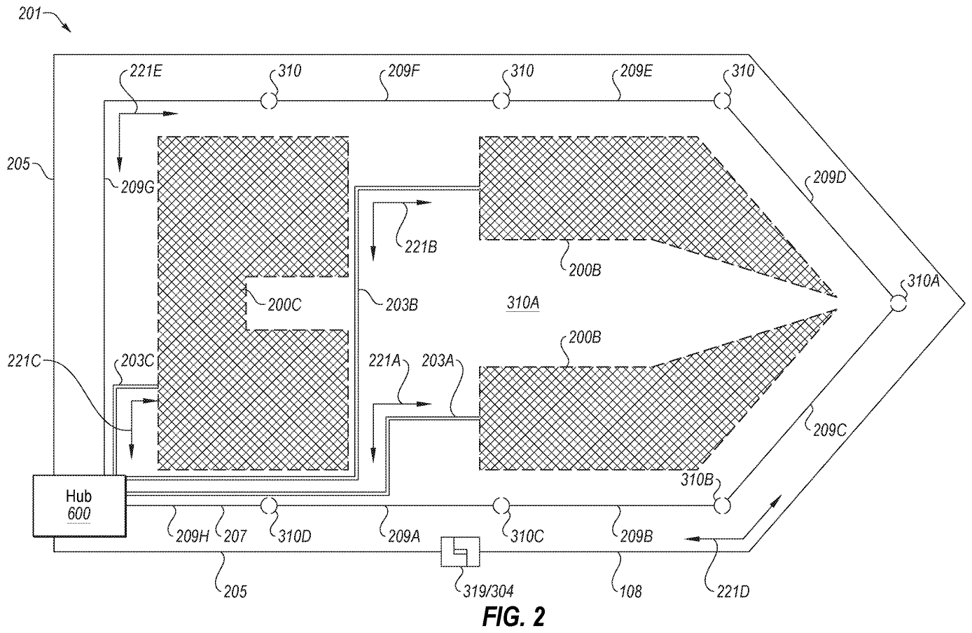

FIG. 2 is a diagram of an example sensor assembly 201 that may be integrated into components (e.g., 102, 104, 300, 310) of the boat cover 100 of FIGS. 1A and 1B or another suitable security cover system. The sensor assembly 201 includes the cut sensor 106 that includes a first mesh 200A, a second mesh 200B, and a third mesh 200C. The sensor assembly 201 also includes the secondary sensor 108 that includes the connector 304. The sensor assembly 201 further includes the additional secondary sensor 113 that includes the snap connectors 310.

The cut sensor 106, the secondary sensor 108, and the additional secondary sensor 113 are communicatively coupled to the hub 600. In the embodiment of FIG. 2, the cut sensor 106 may be communicatively coupled to the hub 600 via cut coupling elements 203A-203C (generally, cut element 203 or cut elements 203). The secondary sensor 108 may be communicatively coupled to the hub 600 via a first communication element 205. The additional secondary sensor 113 may be communicatively coupled to the hub 600 via a second communication element 207.

As introduced with reference to FIGS. 1A and 1B, the sensor assembly 201 or portions thereof may be integrated into components of the boat cover 100. Referring to FIGS. 1A-2, the cut sensor 106 may be integrated between two or more material layers of the fabric portion 102. In particular, the first mesh 200A may be integrated into a first section 115A of the fabric portion 102, the second mesh 200B may be integrated into a second section 115B, and the third mesh 200C may be integrated into a third section 115C. The cut elements 203 may be integrated into the fabric portion 102 to connect one of the meshes 200 to the hub 600. In some embodiments, the fabric portion 102 may include a single layer of material. In these and other embodiments, the cut sensor 106 and/or the cut elements may be attached or adhered to a surface (e.g., an inner surface) of the fabric portion 102. Alternatively, one or more of the meshes 200A-200C may be integrated between layers of the fabric portion 102, while others are attached or adhered to a surface of the fabric portion 102. Additionally, one or more of the cut elements 203 may be attached or adhered to the surface of the fabric portion 102 while others are integrated. For instance, in an embodiment, the first and second meshes 200A and 200C and a first cut element 203A and a second cut element 203B may be integrated into the fabric portion 102 and the third mesh 200C and a third cut element 203C may be adhered to the surface of the fabric portion 102.

The first communication element 205 may be integrated at least partially into the strap 302. For instance, the strap 302 might be comprised of a woven fabric or layers of leather or polymer strips. The first communication element 205 may be integrally woven with the fabric or positioned between the layers of the strips. In some embodiments, some portion of the first communication element 205 may be integrated or adhered to the fabric portion 102. For instance, the portion of the first communication element 205 may be coupled to the hub 600 at one end and extend from the hub 600 to the strap 302. The remaining portion of the first communication element 205 may be integrated into the strap 302. The secondary sensor 108 may include a union connection 319 that may be integrated into the connector 304, which is depicted in FIG. 2 as closed or activated. The union connection 319 of the secondary sensor 108 may include two components having electrical contact that complete a circuit when the connector 304 is engaged or a single component that contacts a circuit contact when the connector is activated. The secondary sensor 108 is configured such that activation of the connector 304 to secure the boat cover 100 completes a circuit with the hub 600. Accordingly, in these and other embodiments, the secondary sensor 108 is integrated into at least a portion of the connector 304.

The second communication element 207 may be composed of several sections 209A-209H (generally, element section 209 or element sections 209). The element sections 209 couple pairs of the snap connectors 310. For instance, a first element section 209A couples a fourth snap connector 310D to a third snap connector 310C. The element sections 209 may be integrated into the perimeter section 104 of the boat cover 100. Alternatively, the element sections 209 may be adhered or affixed to a surface of the perimeter section 104.

The shapes of the meshes 200A-200C may correspond to a shape of a portion of the boat 50 when the boat cover 100 is secured to it. For example, the third mesh 200C may be shaped to extend along an aft portion of the boat 50 and the first and the second meshes 200A and 200B may be triangular to correspond to a forward portion of the boat 50. Additionally, the shapes of the meshes 200A and 200B may be symmetric or substantially symmetric to correspond to the symmetric shape of the boat 50. The shapes and number of the meshes 200A-200C of FIG. 2 are not limiting. For instance, in some embodiments, the sensor assembly 201 may include a single mesh 200 and a single cut element 203 that covers the majority (e.g., the central 70%, 80%, or 90%) of the fabric portion 102. In some embodiments, the sensor assembly 201 may include two meshes 200, one of which is located on a port side and another on a starboard side or one of which located on the forward portion and one of which on the aft portion. In some embodiments, the sensor assembly 201 may include more than three meshes 200. For instance, the sensor assembly 201 may include ten meshes 200. Each of the ten meshes 200 may cover about 10% of the fabric portion 102. The shapes and positions of the meshes 200 may correspond to vulnerable portions of the boat cover 100 when secured to the boat 50. For instance, the meshes 200 may be located around the perimeter or areas where bad actors are likely to access the boat 50 such as the sides, the lower (e.g., closer to the trailer 70) portions.

In an armed state, signals 221A-221E may be communicated through the sensor assembly 201. For instance, in the depicted embodiment, a first signal 221A is communicated from the hub 600 to the first mesh 200A along the first cut element 203A. The first signal 221A is communicated throughout the first mesh 200A and back to the hub 600 via the first cut element 203A. A disruption to the first mesh 200A may interrupt the communication of the first signal 221A to the hub 600. The hub 600 monitors for the signal and triggers an alarm responsive to the interruption. Similarly, a second signal 221B is communicated between the hub 600 and the second mesh 200B via the second cut element 203B, and a third signal 221C is communicated between the hub 600 and the third mesh 200B via the third cut element 203C. Disruptions to the second or the third meshes 200B and 200C interrupts communication of the second or the third signals 221B and 221C, respectively. Such interruptions may trigger the alarm.

A fourth signal 221D may be communicated between the secondary sensor 108 and the hub 600 via the communication element 205. When the connector 304 is engaged or activated, a circuit may be completed, which enables the fourth signal 221D to be communicated through the connector 304. Thus, damage to the communication element 205 or disengagement of the connector 304 may interrupt the fourth signal 221D, which may trigger the alarm.

The additional secondary sensor 113 may include the multiple snap connectors 310. The snap connectors 310 may be open until corresponding snap connectors of the boat are engaged. In these and other embodiments, for a fifth signal 221E to be communicated through the element sections 209, the snap connectors 310 are engaged with the corresponding snap connectors on the boat 50. After the snap connectors 310 are engaged with the corresponding snap connectors of the boat 50, a circuit is completed, which enables communication of the fifth signal 221E. Additionally, removal of the corresponding snap connector from one of the snap connectors 310 prevent communication of the fifth signal 221E. The interruption of the fifth signal 221E may trigger the alarm.

In some embodiments, the signals 221A-221E may be electrical signals. In these embodiments, the sensor assembly 201 is comprised of electrically conductive materials such as conductive metals (e.g., copper, silver, etc.). The electrical signals may include different currents or voltages or may include substantially similar currents (e.g., within about 10% of one another). The disruptions to the sensors 108, 113, and 106 or disruptions to the communicative elements (203, 205, 207) increase electrical resistance. The increase in electrical resistance is measured by the hub 600 or a subsystem thereof. In some embodiments, the signals 221A-221E may include digital signals communicated through one or more of the sensors 108, 113, or 106. The digital signals may be electrical signals or potentially optical signals. Integrity of the meshes 200 may be necessary to communicate the digital signals. Thus, disruptions or damage interrupt such communication, which is measured by the hub 600.

In some embodiments, some subset of the signals 221A-221E may be communicated. For instance, the first, third, and fifth signals 221A, 221C, and 221E may be communicated while the second and fourth signals 221B and 221D may not be communicated. Essentially, not communicating the signals 221 disarm the particular sensor 106, 108, or 113. There may be reasons for disarming one or more of the sensors 106, 108, or 113. For instance, the second mesh 200B may have shorted or otherwise damaged, which causes false alarms. Accordingly, the second signal 221B may not be communicated. Alternatively, the boat 50 may be left in the water making the strap 302 difficult to secure. Accordingly, the fourth signal 221D may not be communicated.

In embodiments in which the subset of signals 221A-221E are not communicated, components of the sensor assembly 201 may be insulated or isolated from one another. For instance, the first mesh 200A may be electrically isolated from the second mesh 200B. Thus the first mesh 200A may be armed and the second mesh 200 may be disarmed.

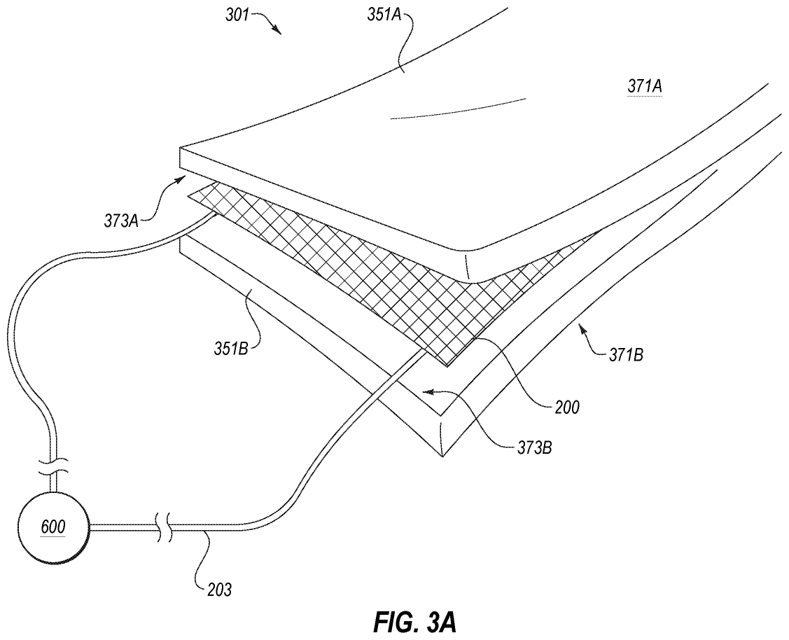

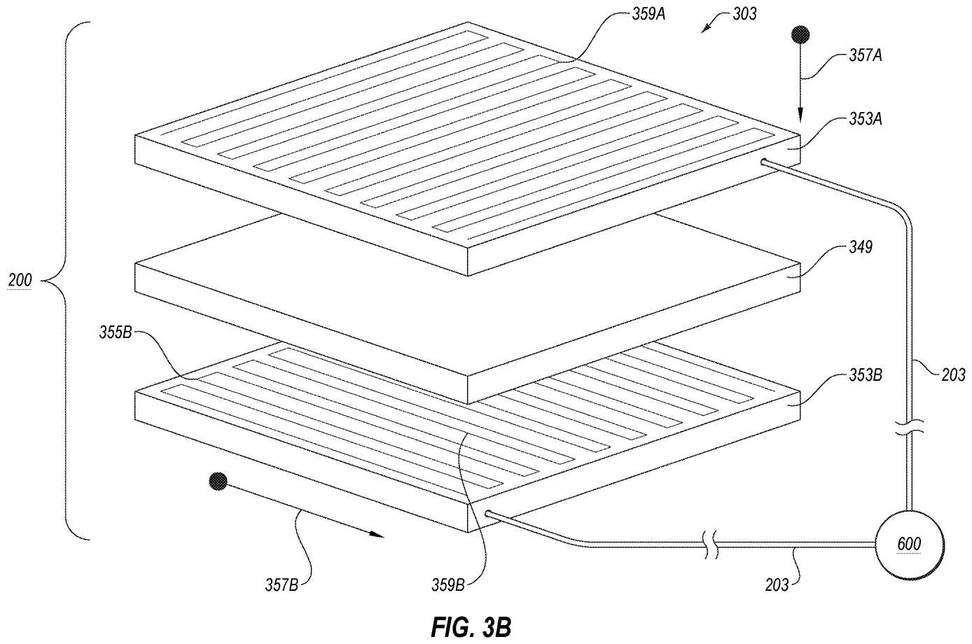

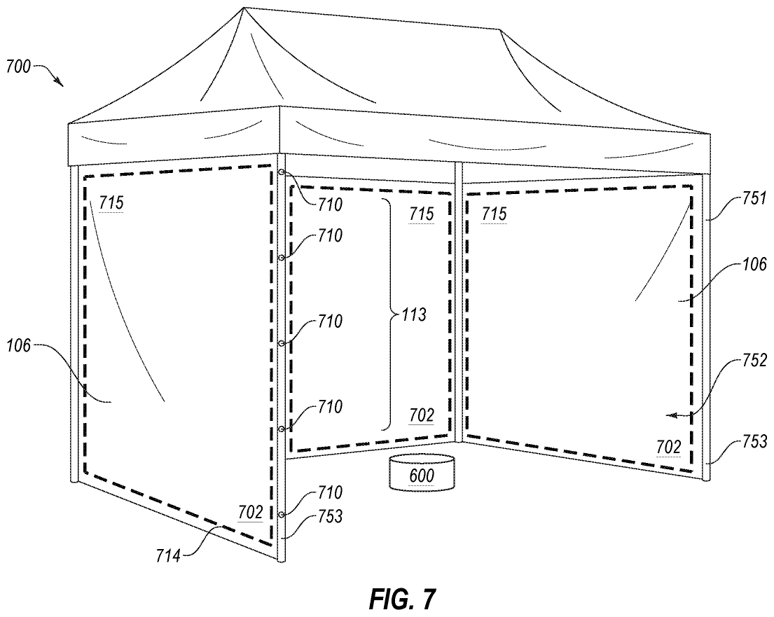

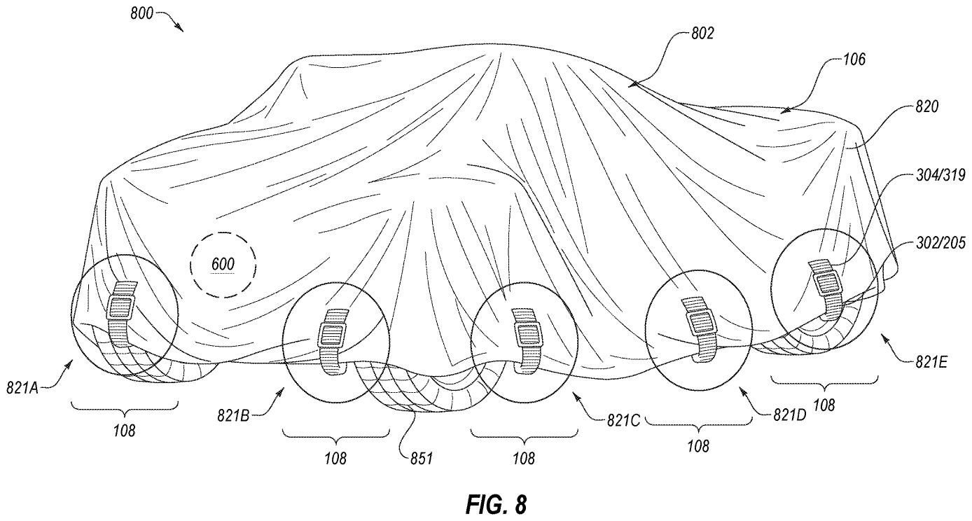

FIGS. 3A and 3B depict an example mesh assemblies 301 and 303. The mesh assemblies 301 and 301 include embodiments of the mesh 200 that may be implemented in the sensor assembly 201 of FIG. 2 and/or the boat cover 100 of FIGS. 1A and 1B or another suitable security cover system. Additionally, the mesh assemblies 301 and 303 may be integrated into other flexible security covers such as those depicted in FIGS. 7 and 8. The mesh assemblies 301 and 303 are described with reference to FIGS. 3A and 3B, respectively.

Referring to FIG. 3A, the mesh 200 may correspond and be substantially similar to one of the meshes 200A, 200B, or 200C of FIG. 2. In a first mesh assembly 301, the mesh 200 is integrated between material layers 351A and 351B (generally, layer 351 or layers 351). One of the material layers 351 may correspond to the outer layer 131 of FIG. 1A. With combined reference to FIGS. 1A and 3A, in some embodiments, a first layer 351A may be an outer layer of material of the fabric portion 102 and a second layer 351B may be an inner layer of material of the fabric portion 102. The inner layer of material at least partially faces the boat 50 when the fabric portion 102 is extended across the gunwale 109. The outer layer of material is subject to an environmental condition when the fabric portion 102 is extended across the gunwale 109. Accordingly, the outer layer may protect the mesh 200 from environmental conditions and may obscure the presence of the mesh 200. The inner layer may also protect the mesh 200 for touch metal component of the boat 50 (e.g., a tower, metal seats, etc.) that may interfere with operation of the mesh 200. In some embodiments, there may be additional layers of material that surround the mesh 200. For instance, the mesh assembly 301 may include four layers that include the first layer 351A, the second layer 351B, and then an additional layer positioned on surface 371A or 371B that is opposite surfaces 373A and 373B that are in contact with the mesh 200. In these and other embodiments, the layers 351 may insulate the mesh 200 and additional layers may provide environmental protection (e.g., water protection, ultraviolet (UV) protection, etc.).

In other embodiments, the first layer 351A and second layer 351B may be insulation layers. For instance, the mesh 200 may be comprised of electrically conduction materials. The layers 351 may be comprised of an electrically isolative material. The electrically isolative material may be a resin or flexible polymer, which may be adhered to the mesh 200. In these embodiments, the mesh assembly 301 may be electrically isolated from the surrounding environment by the layers 351. The mesh assembly 301 may then be adhered to a surface of the fabric portion 102 or may be integrated between an inner layer and outer layer of the fabric portion 102. For instance, an existing cover may be retrofitted with the security features by adhering the mesh assembly 301 to an inner surface of the existing cover.

With combined reference to FIGS. 1A and 3A, the first mesh assembly 301 may be included as parts of the fabric portion 102 such as the sections 115. For instance, the fabric portion 102 may include conventional boat cover material layers without the mesh 200 outside of the sections 115 and the sections 115 may include the first mesh assembly 301.

Referring to FIG. 3B, an additional mesh assembly 303 is depicted. In FIG. 3B, the additional mesh assembly 303 includes a mesh 200 that is woven directly into layers 353A and 353B of material. One of the material layers 353 may correspond to the outer layer 131 of FIG. 1A. For instance, in FIG. 3B in a first layer 353A, a first conductive element 355A is stitched in or woven through the material of a first layer 353A in a first direction, which is generally indicated by arrow 357A. The first conductive element 355A is woven such that elongated elements 359A running in the first direction 357A are separated by a distance and substantially parallel to one another. Accordingly, the first conductive element 355A is comprised of multiple, substantially parallel elongated elements that continue through the first layer 353A. Similarly, a second conductive element 355B is stitched in or woven through the material of a second layer 353B in a second direction, which is generally indicated by arrow 357B. The second conductive element 355B is woven such that elongated elements 359B running in the second direction 357B are separated by a distance and substantially parallel to one another. In some embodiments, the first direction 357A is perpendicular to the second direction 357B or substantially perpendicular (e.g., between about 75 and 105 degrees) to the second direction 357B. Accordingly, in some embodiments, the first layer 353A may include longitudinal conductive elements 355A and the second layer 353B may include latitudinal conductive elements 355B. The longitudinal conductive elements 355A and the latitudinal conductive elements 355B may overlap to form a grid-like pattern. An example of the grid-like pattern is shown in FIG. 3A.

In some embodiments, the elongated elements 359A and 359B are comprised of a conductive material such as a metal thread, a flexible wire, a foil tape, another suitable material, or combinations thereof. Additionally, in some embodiments, the elongated elements 359A and 359B are configured to enable flexibility of the additional mesh assembly 303. For instance, dimensions of the elongated elements 359A and 359B may be about 0.2 millimeters (mm) in some implementations. In other embodiments the dimensions may be greater than 0.2 mm or less than 0.2 mm.

A third layer 349 may be positioned between the layers 353A and 353B. The third layer 349 may be comprised of an insulator to prevent the first conductive element 355A from contacting and electrically coupling to the second conductive element 355B. In some embodiments, the third layer 349 may be omitted. In these embodiments, when a signal is communicated through the first conductive element 355A it may be further communicated through the second conductive element 355B and vice versa.

In some embodiments, the additional mesh assembly 303 may include a single layer 359 that includes conductive elements 355 running in the two directions (e.g., the first and second directions 357A and 357B). In these embodiments, the conductive elements 355 may be interwoven with one another to form a grid-like pattern. Additionally, in some embodiments, the mesh assembly 303 might include three or more layers 359 each of which having conductive elements 355 woven into the material thereof. In these embodiments, the directions of the conductive elements 355 may be offset by a particular angle. For instance, an embodiment having three layers 359, directions of the conductive elements might be 30 degrees from one another.

With combined reference to FIGS. 1A and 3B, the additional mesh assembly 303 may comprise the fabric portion 102 or some sections 115 thereof. For instance, the fabric portion 102 may include conventional boat cover material between the sections 115 and the sections 115 may include the additional mesh assembly 303.

One with skill in the art may understand with the benefit of this disclosure that the mesh assemblies 301 and 303 are not limiting. For instance, with combined reference to FIGS. 3A and 3B, the first mesh assembly 301 and the additional mesh assembly 303 may be combined. That is, the additional mesh assembly 303 may be integrated between the layers 351A and 351B. Additionally, in some embodiments, the first mesh assembly 301 and/or the additional mesh assembly 303 may be implemented multiple times in one cover (e.g., 100) or a portion thereof. For example, the additional mesh assembly 303 may be positioned in a stacked configuration with another, additional mesh assembly 303 or with the first mesh assembly 301. In the stacked configuration, each of the mesh assemblies 301 or 303 may be independently connected to the hub 600, which may enable isolation of one or more of the mesh assemblies 301 and 303.

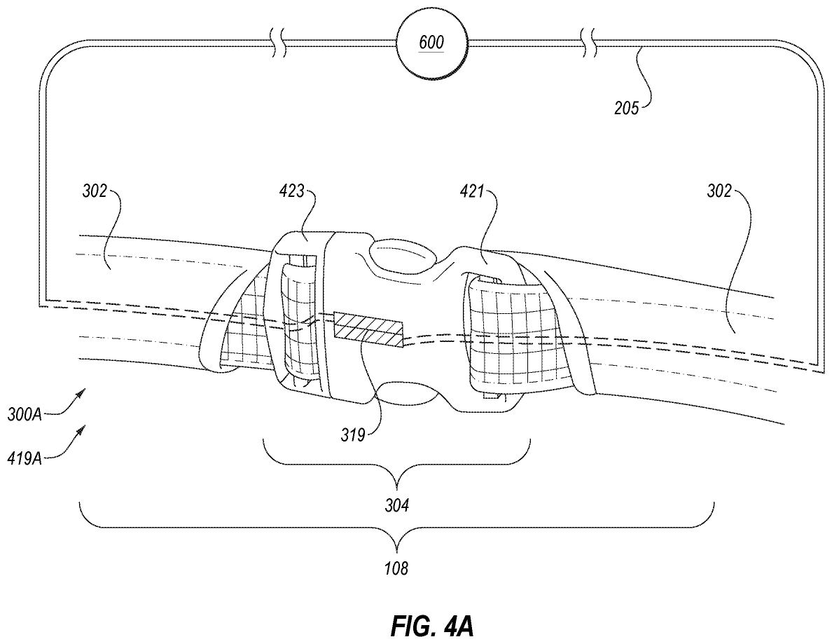

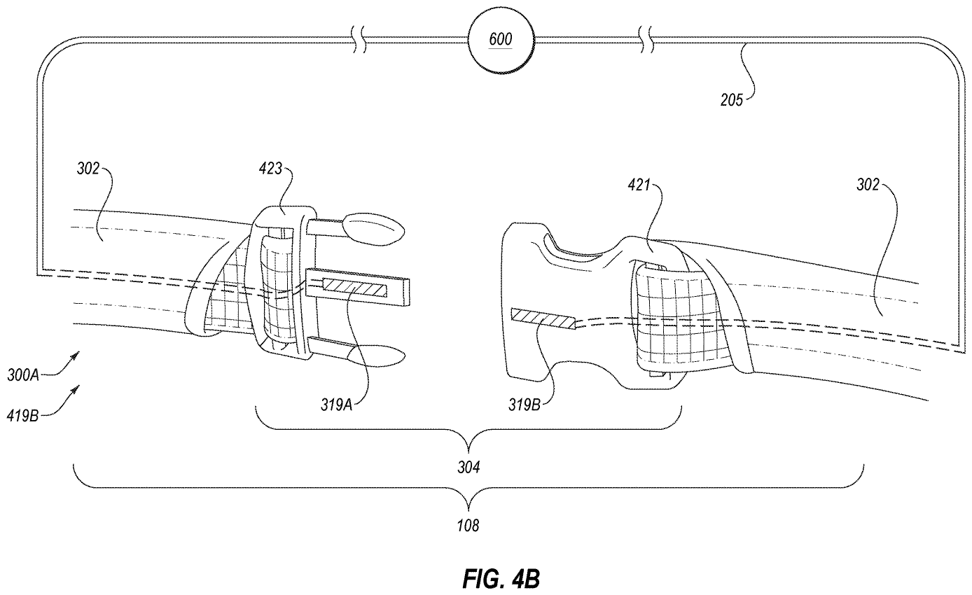

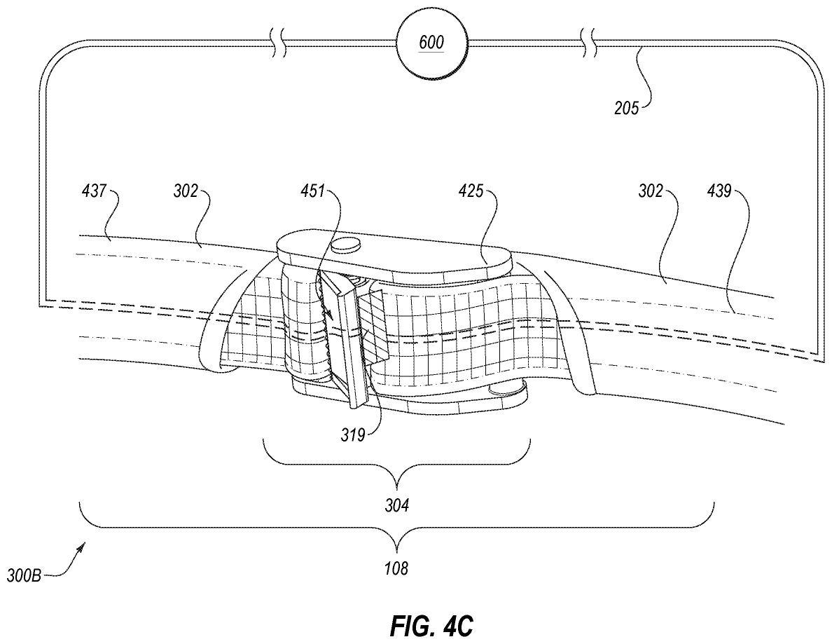

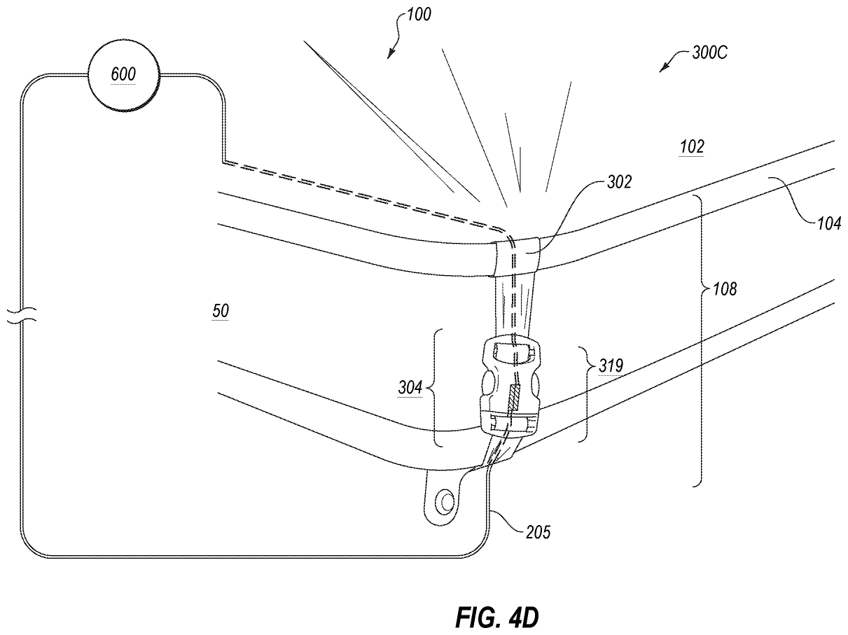

FIGS. 4A-4D depict example embodiments of the secondary sensor 108 integrated into attachment features 300A, 300B, and 300C (generally attachment feature 300 or attachment features 300). The attachment features 300 correspond to and may be substantially similar to the attachment feature 300 introduced with reference to FIGS. 1A-2. The secondary sensors 108 of FIGS. 4A-4D are depicted with the hub 600. FIGS. 4A-4D depict portions of the attachment features 300 and integrated components of the secondary sensor 108. Each of the attachment features 300 are described below. However, one having skill in the art that the attachment features 300 are representative of attachment features into which the secondary sensor 108 may be integrated.

FIGS. 4A and 4B depict a first example connection feature 300A that implements an example of the secondary sensor 108. The first attachment feature 300A includes the connector 304. The connector 304 may be attached to the perimeter section 104 of the boat cover 100 via the strap 302. Additionally or alternatively, the strap 302 may extend over a portion of a fabric portion and hang off an edge of the fabric section. For instance, with reference to FIGS. 1A and 1B, the strap 302 extends over or around the fabric portion 102 and hangs off the perimeter section 104. A loose portion of the strap 302 that hangs off the perimeter section 104 is positioned underneath the hull 122. In FIGS. 4A and 4B, only the ends of the straps 302 engaged with the connector 304 are depicted.

In FIGS. 4A and 4B, the connector 304 is a buckle that includes a receiver 421 and a tongue 423. FIG. 4A depicts the first attachment feature 300A in an engaged configuration 419A. FIG. 4B depicts the first attachment feature 300A in a disengaged configuration 419B. In the engaged configuration 419A of FIG. 4A, the tongue 423 is introduced and secured relative to the receiver 421. In the disengaged configuration 419B of FIG. 4B, the tongue 423 is removed and separate from the receiver 421.

The secondary sensor 108 includes the communication element 205 and the union connection 319. A portion of the communication element 205 may be integrated into or attached to the fabric portion 102 or the perimeter section 104 of the boat cover 100 of FIGS. 1A and 1B. The communication element 205 is coupled to the hub 600. The communication element 205 is further integrated into (e.g., woven into or positioned between layers) of the strap 302.

In the embodiment of FIGS. 4A and 4B, a first portion of the strap 302 is run through the receiver 421 and a second portion of the strap 302 is run through the tongue 423. A first part of the communication element 205 is integrated into the part of the strap 302 that is run through the receiver 421 and a second part of the communication element 205 is integrated in the part of the strap 302 that is run through the tongue 423. The communication element 205 is attached to the union connection 319. As shown in the disengaged configuration 419B of FIG. 4B, the union connection 319 includes a tongue-side portion 319A and a receiver-side portion 319B. When the tongue 423 is separated from the receiver 421, the tongue-side portion 319A does not contact the receiver-side portion 319B. Accordingly, there is no circuit with the hub 600 via which a signal can be communicated. As shown in the engaged configuration 419A of FIG. 4A, the tongue-side portion 319A is engaged with the receiver-side portion 319B because the tongue 423 is received with the receiver 421, which enables the tongue-side portion 319A to contact the receiver-side portion 319B. Accordingly, in the engaged configuration 419A, a circuit with the hub 600 is created via which a signal can be communicated.

Thus, in the engaged configuration 419A, the secondary sensor 108 may be armed. When armed, a signal may be communicated through the secondary sensor 108. When the tongue 423 is disengaged from the receiver 421, the union connection 319 is separated. Specifically, the tongue-side portion 319A is separated from the receiver-side portion 319B, which opens the circuit and prevents the signal from being communicated to the hub 600. Also, cutting or otherwise damaging the strap 302 cuts the communication element 205 and interrupts the signal.

FIG. 4C depicts a second example connection feature 300B that implements an example of the secondary sensor 108. The second attachment feature 300B includes an example of the connector 304. The connector 304 may be attached to a perimeter section of a boat cover via the strap 302 such as the perimeter section 104 of the boat cover 100 of FIGS. 1A and 1B. Additionally or alternatively, the strap 302 may extend over a portion of a fabric portion and hang off an edge of the fabric section. For instance, with reference to FIGS. 1A and 1B, the strap 302 extends over or around the fabric portion 102 and hangs off the perimeter section 104. A loose portion of the strap 302 that hangs off the perimeter section 104 may be positioned underneath the hull 122. In FIG. 4C, only the ends of the straps 302 engaged with the connector 304 are depicted.

In FIG. 4C, the connector 304 is a cinch-type connector that includes a housing 425 and a cinch lever 451. A fixed portion 437 of the strap 302 is attached to the housing 425. An adjustable portion 439 of the strap 302 is routed through the cinch-type connector and pulled back on itself. The cinch lever 451 holds the adjustable portion 439 at a particular position.

In the embodiment of FIG. 4C, the secondary sensor 108 includes the communication element 205 and the union connection 319. A portion of the communication element 205 may be integrated into or attached to the fabric portion 102 or the perimeter section 104 of the boat cover 100 of FIGS. 1A and 1B. The communication element 205 is coupled to the hub 600. The communication element 205 is further integrated into (e.g., woven into or positioned between layers) of the fixed portion 437 of the strap 302 and integrated into the adjustable portion 439 of the strap 302.

The communication element 205 is attached to the union connection 319. The union connection 319 in the embodiment of FIG. 4C includes the cinch lever 451 and an external surface of the adjustable portion 439 of the strap 302. In particular, the communication element 205 integrated in the fixed portion 437 extends to the cinch lever 451. A surface of the cinch lever 451 contacts a conductive element on a surface of the adjustable portion 439 of the strap 302. The contact between the cinch lever 451 and the surface of the adjustable portion 439 creates a circuit with the hub 600 via which a signal may be communicated. Accordingly, when the secondary sensor 108 is armed, the signal is communicated through the communication element 205 of the fixed portion 437, through the cinch lever 451, through the surface connector of the adjustable portion 439 and back to the hub 600 via the communication element 205 integrated into the adjustable portion 439. To change the length of the adjustable portion 439, the cinch lever 451 is disengaged from the surface of the adjustable portion 439, which interrupts the signal and triggers the alarm.

In an alternative embodiment, the secondary sensor 108 of FIG. 4C may include a stretch sensor or a tension sensor, which may be integrated into the adjustable portion 439 and/or the fixed portion 437 of the strap 302. The stretch sensor may be composed of a silicone rubber file that is coated with an electrode on each end. When the material of the stretch sensor is elongated, capacitance between the electrodes may increase because the length increases and a thickness reduces. In these embodiments, the hub 600 may be configured to measure the capacitance or a change in the capacitance after the secondary sensor 108 is armed. A capacitance of a particular amount or a change in capacitance of a particular amount may trigger the alarm. In these embodiments, the union connection 319 may be omitted or the union connection 319 may be used in combination with the stretch sensor. The stretch sensor may also be integrated into the strap 302 of other attachment features, other security features, or the fabric portion to measure elongation.

FIG. 4D depicts a third example connection feature 300C that implements an example of the secondary sensor 108. The third attachment feature 300C includes the connector 304 that is attached to the perimeter section 104 of the boat cover 100 via the strap 302. Although not depicted in FIG. 4D, the strap 302 may extend around or underneath the boat 50 to secure the boat cover 100 to the boat 50.

In FIG. 4D, the connector 304 is a buckle comprised of a receiver and a tongue. The tongue is introduced and secured relative to the receiver. A first portion of the strap 302 is run through the receiver and a second portion of the strap 302 is run through the tongue.

The secondary sensor 108 includes the communication element 205 and the union connection 319. The communication element 205 is integrated into or attached to the fabric portion 102 or the perimeter section 104 of the boat cover 100. The communication element 205 is coupled to the hub 600. The communication element 205 is integrated into (e.g., woven into or positioned between layers) of the strap 302. In the embodiment of FIG. 4D, a first part of the communication element 205 is integrated into the part of the strap 302 run through the receiver and a second part of the communication element 205 is integrated in the part of the strap 302 that is run through the tongue. The communication element 205 is attached to the union connection 319. A first part of the union connection 319 is integrated into the receiver and a second part of the union connection 319 is integrated into the tongue. When the tongue is engaged in the receiver, the union connection 319 completes the circuit with the hub 600 via the communication element 205.

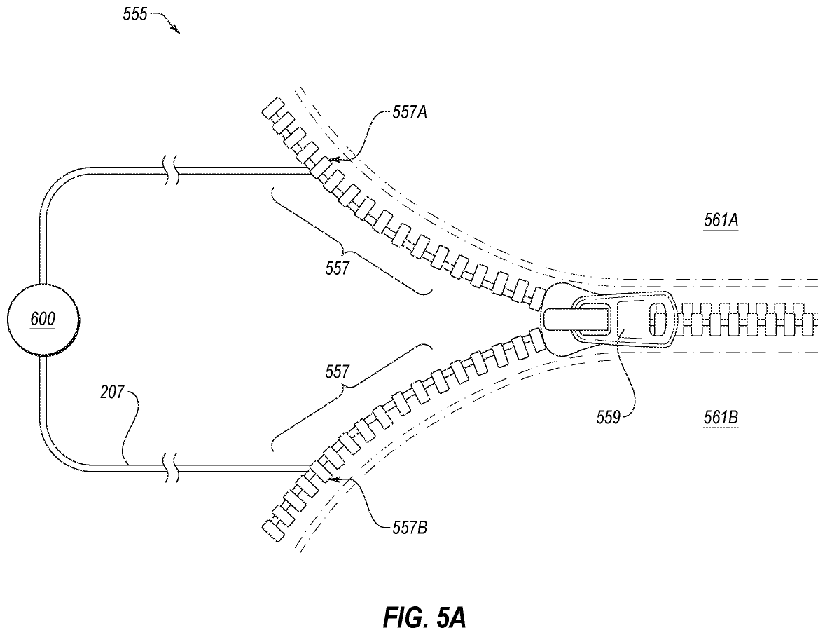

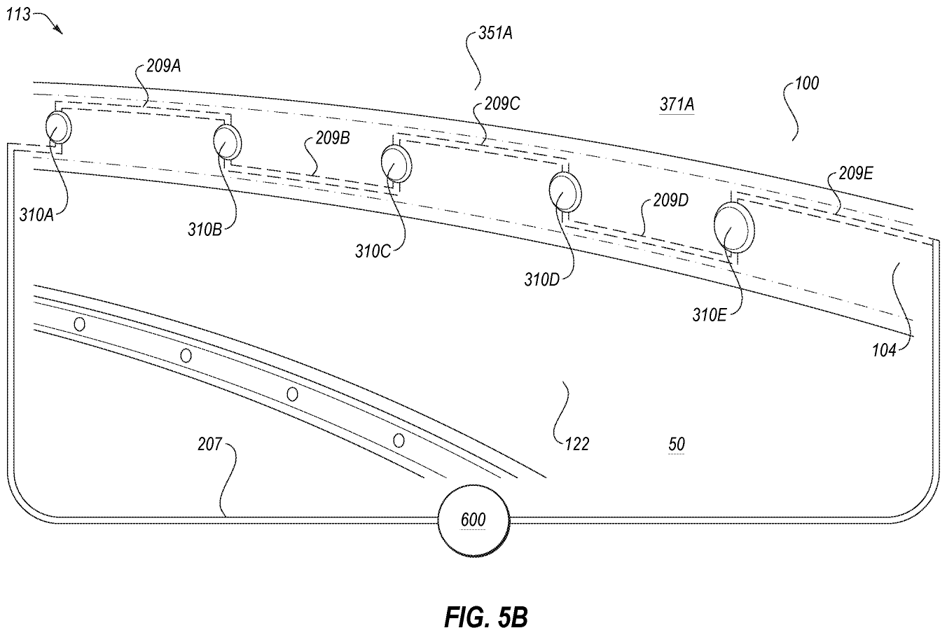

FIG. 5A is a first example of the additional secondary sensor 113. The additional secondary sensor 113 of FIG. 5A is integrated into a zipper 555. The zipper 555 includes multiple teeth 557 that are engaged as a pull tab 559 is moved laterally. When the teeth 557 are engaged, sides 561 are secured relative to one another. In some embodiments, the zipper 555 may be positioned along the edge of a fabric portion such as the fabric portion 102 of FIG. 1A and 1B or 702 of FIG. 7. The second communication elements 207 may be integrated into the sides 561A and 561B and extend to one of a set of the teeth 557A and 557B. When engaged, the set of teeth 557A and 557B complete a circuit with the hub 600 made by the second communication element 207. Accordingly a signal may be communicated via the second communication element 207 and disengagement of the set of teeth 557 may interfere or interrupt the communication of the signal. The hub 600 measures the interruption and triggers an alarm.

In the embodiment of FIG. 5A, the second communication elements 207 may be integrated into a perimeter section of a fabric portion (e.g., 104 of 102). For instance, an electrically conductive wire or thread may be woven into the perimeter section or a part of the fabric portion or may be adhered to a surface of the perimeter section or a part of the fabric section. In the embodiment depicted in FIG. 5A, the set of teeth 557A and 557B includes two teeth 557. In other embodiments more than two teeth 557 may be included in the set of teeth 557A and 557B.

FIG. 5B is a second example of the additional secondary sensor 113. The additional secondary sensor 113 includes element sections 209 that connect snap connectors 310 that are positioned along a perimeter section 104 of the boat cover 100 that is secured relative to the boat 50. When the boat cover 100 is secured to the boat 50, the snap connectors 310 on the boat cover 100 are engaged with corresponding snap connectors on the hull 122. The engagement between the snap connectors 310 and the corresponding snap connectors on the hull 122 complete a circuit with the hub 600 made by the second communication element 207. Accordingly a signal may be communicated via the second communication element 207 and disengagement of the snap connectors 310 may interfere or interrupt the communication of the signal. The hub 600 measures the interruption and triggers an alarm.

Some other sensor types may be included into the additional secondary sensor 113 of FIG. 5B. For instance, the snap connectors 310 may include a reed switch, which is a magnetic switch, which is activated or deactivated by engagement with the corresponding snap connectors on the hull 122. Similarly, the snap connectors 310 may include a hall effect sensor or a magnetic proximity sensor. Again, these sensors are activated or deactivated by engagement with the corresponding snap connectors on the hull 122. Accordingly, after the additional secondary sensor is armed, removal of the snap connectors 310 from the corresponding snap connectors, deactivates the sensor, and breaks a circuit with the hub 600.

In the embodiment of FIG. 5B, the element sections 209 may be integrated into the perimeter section 104. For instance, an electrically conductive wire or thread may be woven into the perimeter section 104 or a part of the fabric portion 102 (of FIGS. 1A and 1B) or may be adhered to a surface of the perimeter section 104 or a part of the fabric portion 102. In the embodiment depicted in FIG. 5B, each of the depicted snap connectors 310 is connected via one of the element sections 209. In some embodiments, only a subset of the snap connectors 310 may be connected via the element sections 209. For instance, every other or every third snap connector 310 may be connective via the element sections 209.

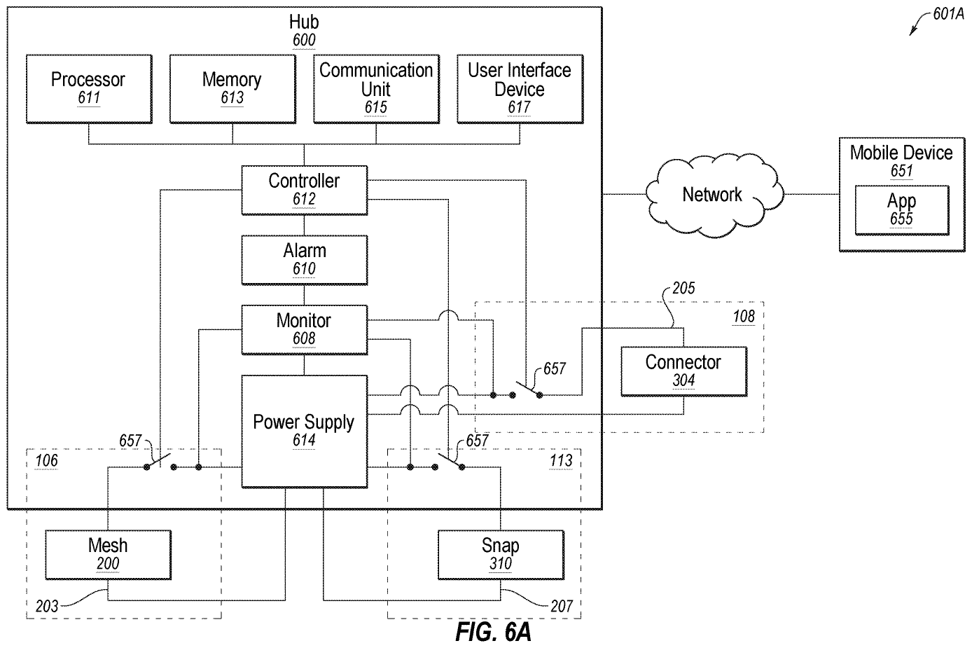

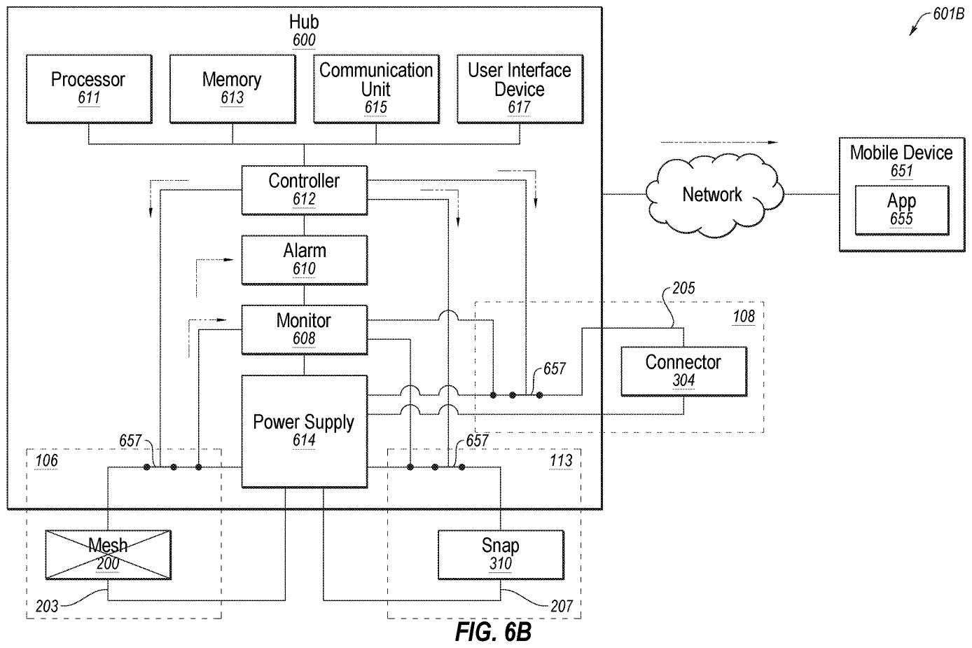

FIGS. 6A and 6B depict a block diagram of an example embodiment of the hub 600 that may be integrated into the boat cover 100 of FIGS. 1A and 1B or another suitable security cover system. The hub 600 is depicted along with an example cut sensor 106, an example secondary sensor 108, and an example additional secondary sensor 113. In other embodiments, the hub 600 may be implemented with sensors 106, 108, or 113. FIG. 6A depicts the hub 600 in a disarmed state 601A and FIG. 6B depicts the system in an armed state 601B.

Referring to FIGS. 6A and 6B, the hub 600 includes a processor 611, memory 613, a communication unit 615, a user interface device 617, a monitor 608, an alarm 610, a controller 612, and a power supply 614.

The processor 611 may include any suitable special-purpose or general-purpose computer, computing entity, or processing device including various computer hardware or software modules and may be configured to execute instructions stored on any applicable computer-readable storage media. For example, the processor 611 may include a microprocessor, a microcontroller, a digital signal processor (DSP), an ASIC, an FPGA, or any other digital or analog circuitry configured to interpret and/or to execute program instructions and/or to process data. Although illustrated as a single processor in FIGS. 6A and 6B, the processor 611 may more generally include any number of processors configured to perform individually or collectively any number of operations described in the present disclosure. Additionally, one or more of the processors 611 may be present on one or more different electronic devices or computing systems. In some embodiments, the processor 611 may interpret and/or execute program instructions and/or process data stored in the memory 613. In some embodiments, the processor 611 may fetch program instructions from the data storage and load the program instructions in the memory 613. After the program instructions are loaded into the memory 613, the processor 611 may execute the program instructions.

The memory 613 may include computer-readable storage media for carrying or having computer-executable instructions or data structures stored thereon. Such computer-readable storage media may include any available media that may be accessed by a general-purpose or special-purpose computer, such as the processor 611. By way of example, and not limitation, such computer-readable storage media may include tangible or non-transitory computer-readable storage media including RAM, ROM, EEPROM, CD-ROM or other optical disk storage, magnetic disk storage or other magnetic storage devices, flash memory devices (e.g., solid state memory devices), or any other storage medium which may be used to carry or store desired program code in the form of computer-executable instructions or data structures and that may be accessed by a general-purpose or special-purpose computer. Combinations of the above may also be included within the scope of computer-readable storage media. Computer-executable instructions may include, for example, instructions and data configured to cause the processor 611 to perform a certain operation or group of operations.

The communication unit 615 may include one or more pieces of hardware configured to receive and send communications. In some embodiments, the communication unit 615 may include one or more of an antennae, a wired port, and modulation/demodulation hardware, among other communication hardware devices. In particular, the communication unit 615 may be configured to receive a communication from outside the hub 600 and to present the communication to the processor 611 or to send a communication from the processor 611 to another device such as a mobile device 651 via a wireless network (e.g., the internet, a wireless telecommunication network, etc.). For instance, in some embodiments, the mobile device 651 or an application 655 may transmit an “arm” command to the hub 600. The “arm” command may be communicated to the processor 611 to transition from the disarmed state 601A of FIG. 6A to the armed state 601B of FIG. 6B. Similarly, the mobile device 651 or the application 655 may communicate a “disarm” command to the hub 600. The “disarm” command may be communicated to the processor 611 to transition from the armed state 601B to the disarmed state 601A.

The user interface device 617 may include one or more pieces of hardware configured to receive input from and/or provide output to a user. In some embodiments, the user interface device 617 may include one or more of a speaker, a microphone, a display, a keyboard, a touch screen, or a holographic projection, among other hardware devices. The user interface device 617 may enable commands directly to the hub 600. For instance, a user might enter the arm or the disarm commands directly to the hub 600, the user might disarm portions of the system (e.g., damaged or failed portions), the user might sync with the application 655 with the hub 600, the user might initiate integrity checks, etc. directly to the hub 600 via the user interface device 617.

The memory 613 may store system modules that include program instructions. The system modules may be programmed to perform one or more functions described herein. The processor 611 may be configured to load the system modules into the memory 613 and execute the system modules. Alternatively, the processor 611 may execute the system modules line-by-line from a data storage without loading them into the memory 613. When executing the system modules, the processor 611 may be configured to perform one or more processes or operations described elsewhere in this disclosure.

The power supply 614 may include a battery or another power storage device. The power supply 614 may be integrated into the hub 600 or otherwise affixed to hub 600 in some embodiments, which may allow for the hub 600 to be portable. In some embodiments, the power supply 614 may not be included in the hub 600 or affixed thereto. In these embodiments, the power supply 614 may be configured to be coupled to an external power source such as an electrical outlet or a solar power cell. The power supply 614 may convert or store external power from the external power source, which is then supplied to the hub 600.

The power supply 614 selectively supplies signals to the sensors 106, 108, and 113. As described elsewhere herein, when armed signals are supplied to the sensors 106, 108, and 113 and when disarmed, the signals are not supplied to the sensors 106, 108, and 113.

The hub 600 may be in operable communication with the cut sensor 106, the secondary sensor 108, and the additional secondary sensor 113. The operable communication between the hub 600 and the cut sensor 106, the secondary sensors 108, and the additional secondary sensor 113 may be selective. For instance, in FIGS. 6A and 6B, the hub 600 may include switches 657. The switches 657 may include be implemented in software (e.g., non-transitory instructions) or may be implemented in hardware (e.g., a semiconductor switch such as a transistor). The switches 657 may be controlled by the controller 612 responsive to an input received at the communication unit 615 or the user interface device 617. For instance, a command may be communicated from an application 655 to the controller 612 to close and open the switches 657. Closing the switches 657 may arm the sensors 106, 108, and 113 by allowing the signals to be supplied to the sensors 106, 108, and 113. Opening the switches 657 may disarm the sensors 106, 108, and 113, by preventing the signals from the communicated to the sensors 106, 108, and 113. In some embodiments, each of the switches 657 may be closed and opened independently, which independently arms or disarms the sensors 106, 108, and 113. Additionally, in some embodiments, the hub 600 may be deactivated, which deactivates the power supply 614 and disarms the sensors 106, 108, and 113.

The monitor 608 is coupled to the cut element 203 and the first and second communication elements 205 and 207 (collectively, elements 203, 205, and 207). The monitor 608 is configured to monitor the sensors 106, 108, and 113 for interruptions to the signals. For instance, the monitor 608 may be configured to identify when the electrical resistance increases, which may be caused by a cut or damage to the mesh 200, damages to the elements 203, 205, and 207 (e.g., cutting a strap into which the elements are integrated), disengagement of the connector 304, or disengagement of the snap connector 310 after the sensors 106, 108, and 113 are armed.

The monitor 608 is coupled to the alarm 610. Responsive to identification of the interruption, the monitor 608 may trigger the alarm 610. In some instances, the alarm 610 is a local audible or visual alarm. Additionally, in some embodiments the alarm 610 is configured to generate a text message, an email message, or an application notification. The alarm 610 may interface with the communication unit 615 to communicate the text message, the email message to the mobile device 651. Additionally, the alarm 610 may interface with the communication unit 615 to push the application notification to the application 655 on the mobile device 651.

FIG. 6A depicts the hub 600 in a disarmed state 601A. In the disarmed state 601A, the switches 657 are open, which prevents signals from being communicated through the sensors 106, 108, and 113. When disarmed, the connector 304 may be engaged and disengaged without triggering the alarm 610. Similarly, when disarmed, the snap connector 310 may be engaged and disengaged with corresponding snap connectors on a boat (e.g., 50 of FIGS. 1A and 1B). In the disarmed state 601A, a boat cover (e.g., 100) or another suitable flexible security cover may be stored or may be secured relative to an object such as the boat. After the flexible security cover is secured relative to the object, the hub 600 may be armed.

As introduced above, the application 655 may communicate an arm command. Additionally or alternatively, the hub 600 may be controlled by a fob, a code might be input to the hub 600 directly via the user interface device 617, or a proximity trigger may communicate the arm command.

In some embodiments, between the disarmed state 601A and armed state 601B, the hub 600 may be configured to perform an integrity check. For instance, the hub 600 may perform a test to ensure the system is properly installed and the system is ready to be armed. The integrity check may identify or disarm specific portions that are inoperable and notify the user.

FIG. 6B depicts the armed state 601B. In the armed state 601B, the switches 657 are closed. For instance, the flexible security cover may be secured to an object. After the flexible security cover is secured to the object, a user may interface with the application 655 and communicate a command to the controller 612 to arm the hub 600. Responsive to the command, the controller 612 may send signals to close the switches 657. In some embodiments, the user may first have to energize the power supply 614 prior to communicating the command. Alternatively, the user may secure the flexible security cover to the object directly press a button on the user interface device 617, which sends the command to the controller 612 to close the switches 657.

When the switches 657 are closed, signals are communicated from the power supply 614 through the elements 203, 205, and 207 which are further communicated through the mesh 200, the snap connector 310, and the connector 304 of the sensors 106, 108, and 113. When armed, the monitor 608 is configured to monitor the signals communicated to the sensors 106, 108, and 113. As long as the signals are not interrupted, the monitor 608 does not trigger the alarm 610. However, responsive to a disruption 670 (e.g., a cut to the mesh 200), the monitor 608 identifies the interruption to the signal (e.g., an increase in resistance preventing communication of the signal). In response the monitor 608 communicates a signal to the alarm 610.

The alarm 610 may be triggered by the signal communicated from the monitor 608. In some embodiments, the alarm 610 includes a local audible alarm. Additionally or alternatively, the alarm 610 may generate a text message, an email, or a push notification. The text message, the email, or the push notification may be communicated to the communication unit 615, which communicates the message to the application 655 via the network.

FIG. 7 depicts another example embodiment of a flexible security cover 700 implemented on a kiosk 751. Like the boat cover 100 of FIGS. 1A and 1B, the flexible security cover 700 may include security features such as one or more the cut sensor(s) 106, one or more secondary sensor(s) 108, one or more additional secondary sensor(s) 113, or some combination thereof. Additionally, the flexible security cover 700 may include multiple fabric portions 702 that envelope the sides and back of the kiosk 751. In some embodiments, an additional fabric portion 702 may be positioned along a front opening 752 of the kiosk 751.

The fabric portions 702 may integrate meshes 720 in one or more sections 715 of the fabric portions 702. The meshes 720 are substantially similar to the mesh 200 described elsewhere in the present disclosure. For instance, the meshes 720 may be communicatively coupled to the hub 600 via cut elements 203. When armed, a signal may be communicated through the meshes 720. A disruption or breach to one or more of the meshes 720 interrupts the signal, which triggers the alarm of the hub 600.

Additionally, the fabric portions 702 may be secured relative to the kiosk 751 along posts 753. In the depicted embodiment, the fabric portion 702 is attached by snap connectors 710. The snap connectors may include an additional secondary sensor 113. For instance, the snap connectors 710 may be integrated into a perimeter section 714 of one of the fabric portions 702. When the snap connectors 710 are engaged with corresponding snap connectors on the posts 753, a circuit with the hub 600 may be complete. An additional signal may be communicated through the additional secondary sensor 113 including the snap connectors 710. Responsive to the snap connectors 710 being disengaged from the corresponding snap connectors on the posts 753, the additional signal may be interrupted.

Alternatively, the fabric portions 702 may include the additional secondary sensor 113 of FIG. 5B that is integrated into a zipper. The zipper may be positioned along the perimeter section 714 or some portion thereof. When the sides of the zipper are engaged, the circuit with the hub 600 may be created. The additional signal may be communicated through the additional secondary sensor 113 when it is armed. Unzipping the zipper may interrupt the additional signal, which may be identified by the hub 600, which triggers the alarm.

Although not depicted in FIG. 7, the flexible security cover 700 might include the secondary sensor 108 integrated into an attachment feature depicted in one or more of FIGS. 4A-4C. The attachment feature might include straps (e.g., 302) that extend from the fabric portions 702 that are fitted with a connector (e.g., 304). The fabric portions 702 and the straps may integrate the secondary communication element 205 which are coupled to the hub 600. The attachment feature may be used to secure the flexible security cover 700 relative to the kiosk 751. When armed, a signal may be communicated through the secondary sensor 108. Cutting the strap or disengaging the connector interrupts the signal, which triggers the alarm.

FIG. 8 depicts another example embodiment of a flexible security cover 800 implemented on a vehicle 851. Like the boat cover 100 of FIGS. 1A and 1B, the flexible security cover 800 may include security features such as one or more the cut sensor(s) 106, one or more secondary sensor(s) 108, one or more additional secondary sensor(s) 113, or some combination thereof.

The flexible security cover 800 includes a fabric portion 802 that envelopes the vehicle 851. The fabric portions 802 may integrate a mesh 820 in the fabric portions 702. The mesh 820 is substantially similar to the mesh 200 described elsewhere in the present disclosure. For instance, the meshes 820 may be communicatively coupled to the hub 600 via cut elements 203. When armed, a signal may be communicated through the meshes 820. A disruption or breach to the mesh 820 interrupts the signal, which triggers the alarm of the hub 600.

The fabric portion 802 includes multiple secondary sensors 108 integrated into attachment features 821A-821E. The attachment features 821A-821E are similar to the attachment features 300A and 300C of FIGS. 3A and 3B. Each of the attachment features 821A-821E includes a strap 302 that extends from the fabric portion 802 that is fitted with a connector 304. The fabric portion 802 and the strap 302 may integrate the secondary communication element 205 which are coupled to the hub 600. The connectors 304 include the union connection 319. The attachment features 821A-821E may be used to secure the flexible security cover 800 relative to the vehicle 851. When armed, a signal may be communicated through the secondary sensors 108. Cutting the strap or disengaging the connectors 304 interrupts the signal, which triggers the alarm.

The depicted embodiments are not meant to be limiting to use of the flexible security cover described herein. For instance, the flexible security cover may be used for any object. For example, the flexible security cover may be used to cover portions of boats, motorcycles, automatic teller machines, pools, furniture, musical instruments, etc.

The various features illustrated in the drawings may not be drawn to scale. The illustrations presented in the present disclosure are not meant to be actual views of any particular apparatus (e.g., device, system, etc.) or method, but are representations employed to describe embodiments of the disclosure. Accordingly, the dimensions of the features may be expanded or reduced for clarity. In addition, some of the drawings may be simplified for clarity. Thus, the drawings may not depict all of the components of a given apparatus (e.g., device) or all operations of a particular method.

Terms used in the present disclosure and the claims (e.g., bodies of the appended claims) are intended as “open” terms (e.g., the term “including” should be interpreted as “including, but not limited to,” the term “having” should be interpreted as “having at least,” the term “includes” should be interpreted as “includes, but is not limited to,” among others). Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations.

In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in instances in which a convention analogous to “at least one of A, B, and C, etc.” or “one or more of A, B, and C, etc.” is used, in general such a construction is intended to include A alone, B alone, C alone, A and B together, A and C together, B and C together, or A, B, and C together, etc. Further, any disjunctive word or phrase presenting two or more alternative terms should be understood to contemplate the possibilities of including one of the terms, either of the terms, or both terms. For example, the phrase “A or B” should be understood to include the possibilities of “A” or “B” or “A and B.”

However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations.

The terms “first,” “second,” “third,” etc., are not necessarily used to connote a specific order or number of elements. Generally, the terms “first,” “second,” “third,” etc., are used to distinguish between different elements as generic identifiers. Absence a showing that the terms “first,” “second,” “third,” etc., connote a specific order, these terms should not be understood to connote a specific order. Furthermore, absence a showing that the terms “first,” “second,” “third,” etc., connote a specific number of elements, these terms should not be understood to connote a specific number of elements. For example, a first widget may be described as having a first side and a second widget may be described as having a second side. The use of the term “second side” with respect to the second widget may be to distinguish such side of the second widget from the “first side” of the first widget and not to connote that the second widget has two sides.

All examples and conditional language recited herein are intended for pedagogical objects to aid the reader in understanding the invention and the concepts contributed by the inventor to furthering the art and are to be construed as being without limitation to such specifically recited examples and conditions. Although embodiments of the present inventions have been described in detail, it should be understood that the various changes, substitutions, and alterations could be made hereto without departing from the scope of the invention.

What is claimed is:

1. A security cover system, comprising:
a fabric portion surrounded by a perimeter section, the fabric portion being sized to be selectively extended to envelop or partially enclose an object;
a cut sensor integrated into a first section of the fabric portion, the cut sensor including a mesh integrated into material of the fabric portion, wherein the cut sensor is configurable in an armed state in which a signal is communicated through the mesh and disruption to the mesh interrupts communication of the signal;
a hub in operable communication with the cut sensor such that interruption to the signal is identified by the hub and responsive to identification of the interruption, the hub generates and communicates an alarm.

2. The security cover system of claim 1, further comprising:
an object attachment feature including a connector that is configured to selectively secure the flexible portion relative to the object; and
a secondary sensor associated with the object attachment feature, the secondary sensor being configurable in the armed state in which an additional signal is communicated through the connector such that disengagement of the connector interrupts the additional signal;
wherein the hub is in operable communication with the secondary sensor such that the disengagement of the connector is identified by the hub and responsive to the identification of the disengagement, the hub generates and communicates the alarm.

3. The security cover system of claim 2, wherein the cut sensor and the secondary sensor are further configurable in a disarmed state during which the signal and the additional signal are not communicated.

4. The security cover system of claim 2, further comprising a secondary sensor communication element; wherein:
the object attachment feature is positioned on a portion of the perimeter section;
the connector includes a snap in the portion of the perimeter section;
the secondary sensor communication element is integrated in the portion of the perimeter section; and
the hub is in operable communication with the snap via the secondary sensor communication element.

5. The security cover system of claim 2, further comprising a secondary sensor communication element; wherein:
the object attachment feature includes a strap attached to a portion of the perimeter section at a first end;
the connector is included on a second end of the strap;
the secondary sensor communication element is integrated in the portion of the perimeter section and the strap; and
the hub is in operable communication with the connector via the secondary sensor communication element.

6. The security cover system of claim 1, wherein:
the mesh includes an electrically conductive mesh;
the signal includes an electrical signal introduced to the electrically conductive mesh; and
the disruption to the mesh includes a physical break to a portion of the mesh that prevents communication of the electrical signal.

7. The security cover system of claim 6, wherein:
the electrically conductive mesh includes multiple elongated conductive elements including longitudinal conductive elements and latitudinal conductive elements;
the longitudinal conductive elements are oriented substantially perpendicular to the latitudinal conductive elements; and
the longitudinal conductive elements are interwoven with the latitudinal conductive elements.

8. The security cover system of claim 1, wherein:
the fabric portion includes multiple layers of the material, the multiple layers including an outer layer and an inner layer;
the outer layer is subject to an environmental or ambient condition when the fabric portion is extended to envelop or partially envelop the object;
the inner layer is at least partially facing the object when the fabric portion is extended to envelop or partially envelop the object; and
the mesh is integrated between the outer layer and the inner layer in the first section of the fabric portion.

9. The security cover system of claim 1, further comprising an additional cut sensor, wherein:
the mesh includes a first mesh;
the signal includes a first signal;
the fabric portion includes a second section in which the additional cut sensor is integrated;
the additional cut sensor is integrated into the second section of the fabric portion;
the additional cut sensor includes an additional mesh integrated into material of the fabric portion,
the additional mesh is isolated from the first mesh;
the additional mesh is configurable in the armed state in which an additional signal is communicated through the additional mesh and disruption to the additional mesh interrupts communication of the additional signal without interruption to the first signal; and
the hub is in operable communication with the additional cut sensor such that interruption to the additional signal is identified by the hub and responsive to identification of the interruption, the hub generates and communicates an additional alarm indicating interruption of the additional signal but not interruption of the first signal.

10. The security cover system of claim 9, wherein the first cut sensor is configurable in the armed state while the additional cut sensor is configured in a disarmed state.

11. The security cover system of claim 1, wherein an edge of the first section is located immediately adjacent to the perimeter section and surrounds the fabric portion.

12. The security cover system of claim 1, wherein the object includes a kiosk, a boat, a vehicle, a portion of a vehicle, or a pallet.

13. A boat cover including a security system, the boat cover comprising:
a fabric portion surrounded by a perimeter section, wherein:
the fabric portion is sized to be selectively extended across a gunwale of a boat to enclose or substantially enclose a portion of a cockpit of the boat;
the perimeter section is located along an edge of the fabric portion; and
the fabric portion is comprised of an inner layer of material that at least partially faces the boat when the fabric portion is extended across the gunwale and an outer layer of material that is subject to an environmental condition when the fabric portion is extended across the gunwale;
a cut sensor integrated into a first section of the fabric portion, the cut sensor including a mesh integrated between the outer layer and the inner layer, wherein the cut sensor is configurable in an armed state in which a first signal is communicated through the mesh and disruption to the mesh interrupts communication of the signal;
an attachment feature that is configured to selectively secure the flexible portion relative to the boat;
a secondary sensor associated with the attachment feature, the secondary sensor being configurable in the armed state in which an additional signal is communicated through an element of the attachment feature such that disengagement of the attachment feature interrupts the additional signal; and
a hub in operable communication with the cut sensor and the secondary sensor, wherein the hub includes:
a monitor that identifies an interruption to the first signal and interruption of the additional signal, and
an alarm that is triggered responsive to identification of the interruption of the first signal or the interruption of the additional signal.

14. The boat cover of claim 13, wherein the cut sensor and the secondary sensor are further configurable in a disarmed state in which the first signal and the additional signal are not communicated, and the monitor is configured in a passive state in which the interruption to the first signal and the interruption of the additional signal do not trigger the alarm.

15. The boat cover of claim 14, wherein:
the electrically conductive mesh includes multiple elongated conductive elements including longitudinal conductive elements and latitudinal conductive elements;
the longitudinal conductive elements are oriented substantially perpendicular to the latitudinal conductive elements; and
the longitudinal conductive elements are interwoven with the latitudinal conductive elements.

16. The boat cover of claim 13, wherein the mesh includes:
the mesh includes an electrically conductive mesh;
the signal includes an electrical signal introduced to the electrically conductive mesh; and
the disruption to the mesh includes a physical break to a portion of the mesh that prevents communication of the electrical signal.

17. The boat cover of claim 16, wherein:
the attachment feature further includes a strap having a first portion that is fixed to the perimeter section;
the secondary sensor includes a secondary communication element that is integrated into a portion of the perimeter section and at least a portion of the strap;
the secondary communication element links to the connector to the hub;
in the armed state the additional signal is communicated through the secondary communication element and disruption to the secondary communication element interrupts communication of the additional signal;
the monitor is further configured to identify interruption of the additional signal communicated through the secondary communication element; and
an alarm that is triggered responsive to identification of the additional signal interruption.

18. The boat cover of claim 13, wherein:
the attachment feature includes a connector;
the connector is configurable in an engaged arrangement and a disengaged arrangement;
in the engaged arrangement the perimeter section is fixed relative to the boat and an additional signal circuit in which the additional signal is communicated is complete;
in the disengaged arrangement the additional signal circuit is incomplete; and
the disengagement of the attachment feature includes configuring the connector in a disengaged configuration.

19. The boat cover of claim 13, wherein the alarm includes one or more or a combination of:
a local audible alarm;
a text message communicator;
an email message communicator; and
an application notification push communicator.

20. The boat cover of claim 13, further comprising an additional cut sensor, wherein:
the mesh includes a first mesh;
the fabric portion includes a second section in which the additional cut sensor is integrated;
the additional cut sensor is integrated into the second section of the fabric portion;
the additional cut sensor includes an additional mesh integrated into the material of the fabric portion,
the additional mesh is isolated from the first mesh;
the additional mesh is configurable in the armed state in which a second signal is communicated through the additional mesh and disruption to the additional mesh interrupts communication of the second signal without interruption to the first signal; and
the hub is in operable communication with the additional cut sensor such that interruption to the second signal is identified by the monitor and responsive to identification of the interruption, the alarm is triggered.
